(19) United States
(12) Patent Application Publication
(10) Pub. No.: US 2014/0124900 A1
(43) Pub. Date: May 8, 2014

(54) THROUGH-SILICON VIA (TSV) DIE AND METHOD TO CONTROL WARPAGE

(71) Applicant: TEXAS INSTRUMENTS INCORPORATED, Dallas, TX (US)

(72) Inventors: JEFFREY ALAN WEST, DALLAS, TX (US); MARGARET SIMMONS-MATTHEWS, RICHARDSON, TX (US); RAJESH TIWARI, PLANO, TX (US)

(73) Assignee: TEXAS INSTRUMENTS INCORPORATED, Dallas, TX (US)

(21) Appl. No.: 13/667,715

(22) Filed: Nov. 2, 2012

(51) Int. Cl. H01L 23/48; H01L 21/304; H01L 21/306

(52) U.S. Cl. 257/621; 438/692; 257/E23.011; 257/E21.23

(57) ABSTRACT

A through-substrate via (TSV) die includes a substrate having a top side semiconductor surface having active circuitry therein including a plurality of transistors functionally connected and a bottom side surface, wherein the layers on the top side semiconductor surface exert a net tensile stress to the top side semiconductor surface. A plurality of TSVs which extend from the top side semiconductor surface to TSV tips which protrude from the bottom side surface include an inner metal core surrounded by a dielectric liner that forms an outer edge for the TSVs. A dielectric stack is on the bottom side surface lateral to the TSV tips including a compressive dielectric layer and a tensile dielectric layer on the compressive dielectric layer.

### FIELD

Disclosed embodiments generally relate to the fabrication of integrated circuit (IC) devices and, more specifically, to fabricating through-substrate via (TSV) die having TSV tips.

### BACKGROUND

As known in the art, through-substrate vias (referred to herein as TSVs), which are commonly referred to as through-silicon vias in the case of silicon substrates, are vertical electrical connections that extend the full thickness of the substrate. TSVs extend from one of the electrically conductive levels formed on the top side surface of the semiconductor die (e.g., contact level or one of the back end of the line (BEOL) metal interconnect levels) to at least its bottom side surface. Such semiconductor die are referred to herein as “TSV die.”

TSVs are generally framed by a dielectric liner and are then filled with copper or another electrically conductive TSV filler material to provide a low resistance vertical electrical connection though the die. A diffusion barrier metal formed on the dielectric liner frames the TSV and protects against escape of the TSV filler material into the semiconductor in the case of highly mobile metal TSV filler materials, such as copper.

The vertical electrical paths provided by TSVs are significantly shortened in length relative to conventional wire bonding technology, generally leading to significantly faster device operation. In one arrangement, the TSVs terminate on the bottom side of the TSV die as protruding TSV tips, such as protruding a distance of 3 μm to 15 μm from the bottom side substrate (e.g., silicon) surface. To form the protruding tips, the TSV die are commonly thinned in wafer form while bonded to a carrier wafer which provides mechanical support to expose the TSVs and to form the TSV tips, such as to a die thickness of 25 μm to 100 μm, using a process generally including backgrinding. The TSV die can be bonded face-up or face-down, and can be bonded to from both of its sides to enable formation of stacked (3 dimensional) devices.

Following revealing of the TSVs, the TSV wafer is debonded from the carrier wafer. Since the TSV wafer may only be 25 μm to 100 μm thick, the TSV wafer is prone to significant bow and possible breakage due to stress from the metal interconnect and interlevel dielectric (ILD) layers on the top side of the wafer, particularly when there is significant total composite tensile stress on the top side of the wafer.

Known solutions to TSV wafer bow and breakage caused by thin TSV wafers include use of polymeric isolation on the bottom side of the wafer, and modifying the top side layers to change the stress, such as to achieve a net compressive stress. Another solution utilizes an alternate wafer support systems that does not attempt handling of unsupported thinned (e.g., <100 μm) TSV wafers at carrier debond. Such systems can eliminate the handling issues associated with handling bowed thin TSV wafers, but generally significantly increase the cost of the assembly process.

### SUMMARY

Disclosed embodiments include methods of forming through substrate vias (TSV) die (“TSV die”) including protruding TSV tips that protrude from a bottom side of the substrate. Disclosed embodiments recognize when the total stress due to the layers on the top side semiconductor surface of a thinned TSV wafer (e.g. <100 μm) are significantly tensile, substrate (e.g., wafer) bow/warpage and breakage of the thin TSV substrate can occur during the carrier wafer debond operation and subsequent assembly steps. Moreover, cracking of the dielectric on the bottom side of the TSV die (potentially triggered by bottom side chemical mechanical polishing (CMP) processing to reveal the TSV tips) can lead to reliability or electrical failures of the TSV die.

Disclosed methods deposit a dielectric stack on the bottom side of the TSV substrate after substrate thinning to offset (compensate for) the bow in the substrate induced by layers on the top side of the TSV wafer. The dielectric stack comprises a compressive dielectric layer on the bottom side surface, and a tensile dielectric layer on the compressive dielectric layer. An optional third layer can be provided on the tensile dielectric layer to provide a sacrificial compressive layer (e.g., tetraethyl orthosilicate (TEOS) derived silicon oxide) to minimize the opportunity for CMP-induced cracking of the underlying tensile dielectric layer (e.g., silicon nitride (SiN)) that can otherwise occur when polishing the dielectric stack to re-reveal the distal ends of the TSV tips.

Disclosed embodiments simultaneously solve several problems encountered when conventionally assembling thin TSV substrates. Substrate bow is addressed by providing bow compensation, handling breakage that can occur during the carrier debond operation is reduced, and bottom side (TSV tip re-reveal) CMP-induced cracks that can occur in a highly tensile inorganic isolation layer that might otherwise lead to reliability or electrical failures of the TSV die are suppressed.

### BRIEF DESCRIPTION OF THE DRAWINGS

Reference will now be made to the accompanying drawings, which are not necessarily drawn to scale, wherein:

FIG. 1 is a flow chart showing steps in an example method of forming TSV die having a plurality of TSVs including a bow compensating dielectric stack on the bottom side of the die, according to a disclosed embodiment.

FIGS. 2A-D show successive simplified cross sectional depictions corresponding to steps in an example method of fabricating TSV die having a plurality of TSVs including a bow compensating dielectric stack on the bottom side of the die, according to an example embodiment.

FIG. 3 is a simplified cross sectional depiction of an example TSV die having a plurality of TSVs including a bow compensating dielectric stack on the bottom side of the die, according to an example embodiment.

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

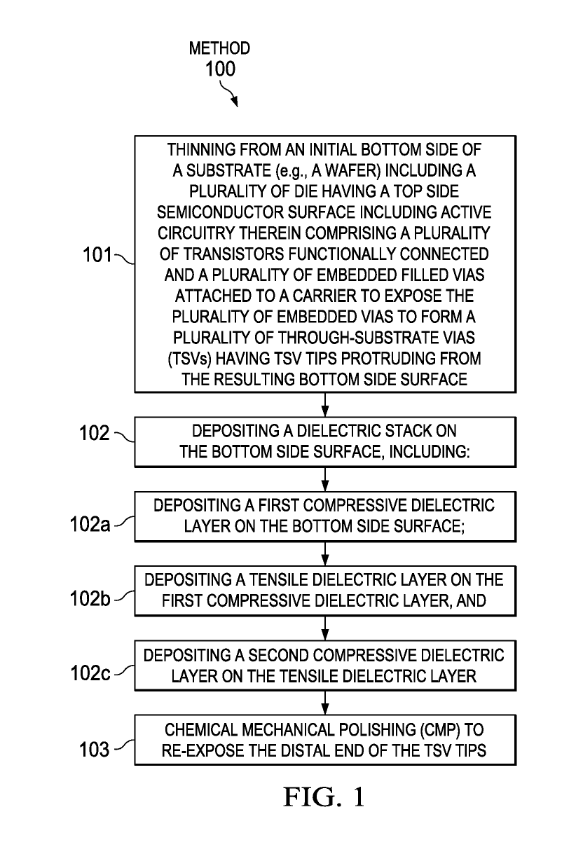

FIG. 1 is a flow diagram illustrating an example method 100 of forming TSV die having a plurality of TSVs including a bow compensating dielectric stack on the bottom side of the die, according to an example embodiment. Step 101 comprises thinning from an initial bottom side of a substrate (e.g., a wafer) having a top side semiconductor surface including active circuitry therein comprising a plurality of transistors functionally connected and a plurality of embedded filled vias attached to a carrier to expose the plurality of embedded vias to form a plurality TSVs having TSV tips protruding from the resulting bottom side surface. The top side semiconductor surface can comprise silicon, silicon germanium, or other materials.

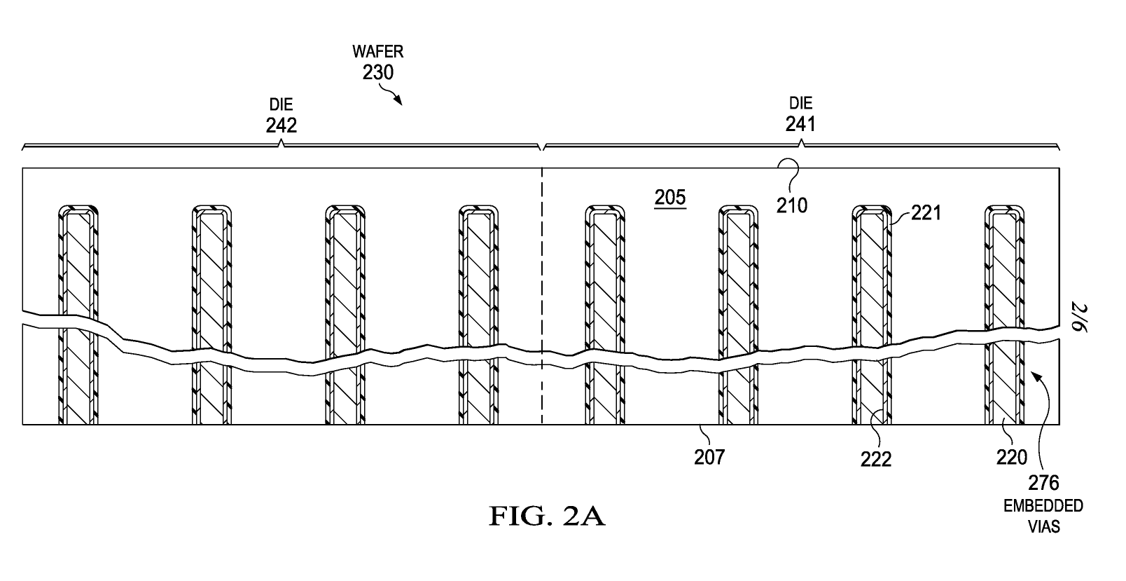

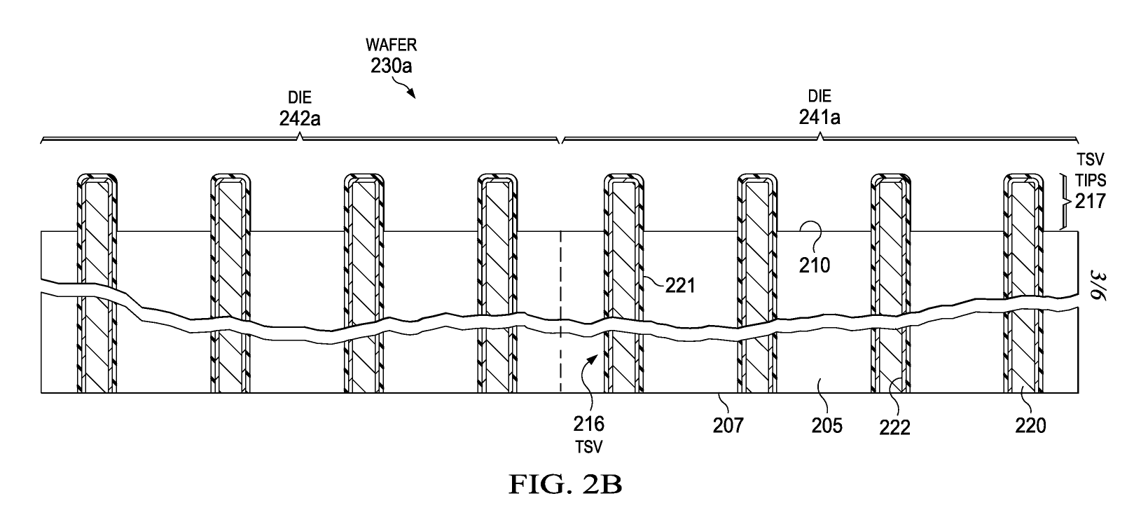

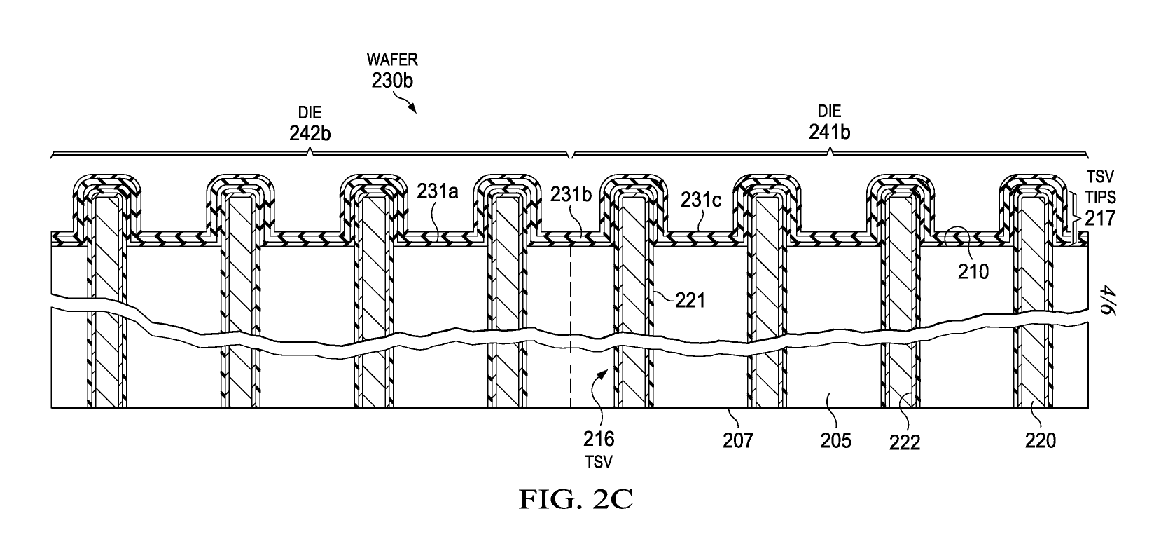

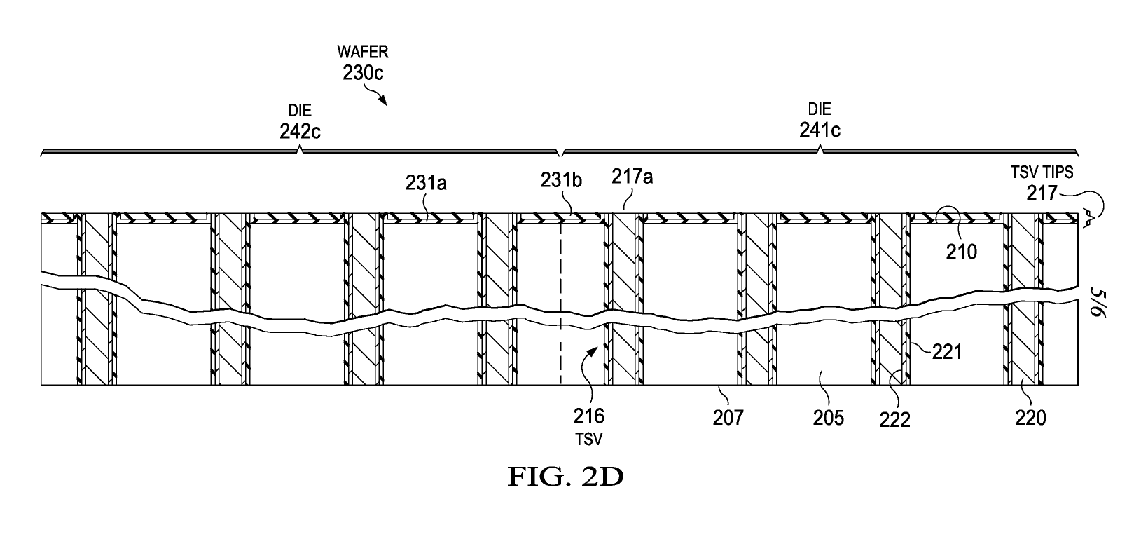

FIG. 2A shows a simplified cross sectional depiction of a wafer 230 comprising a plurality of die 241, 242 including a substrate 205 having a plurality of embedded vias 276 including a top side semiconductor surface 207 and bottom side surface 210 after bottom side wafer thinning, such as using a carrier wafer-based backgrinding process. For example, the wafer 230/substrate 205 may be thinned to a thickness of 60 μm to 80 μm from an initial (pre-thinning) thickness of about 500 μm to 775 μm. The distance between the distal end of the embedded vias 276 and the bottom side surface 210 may be about 8 μm±4 μm.

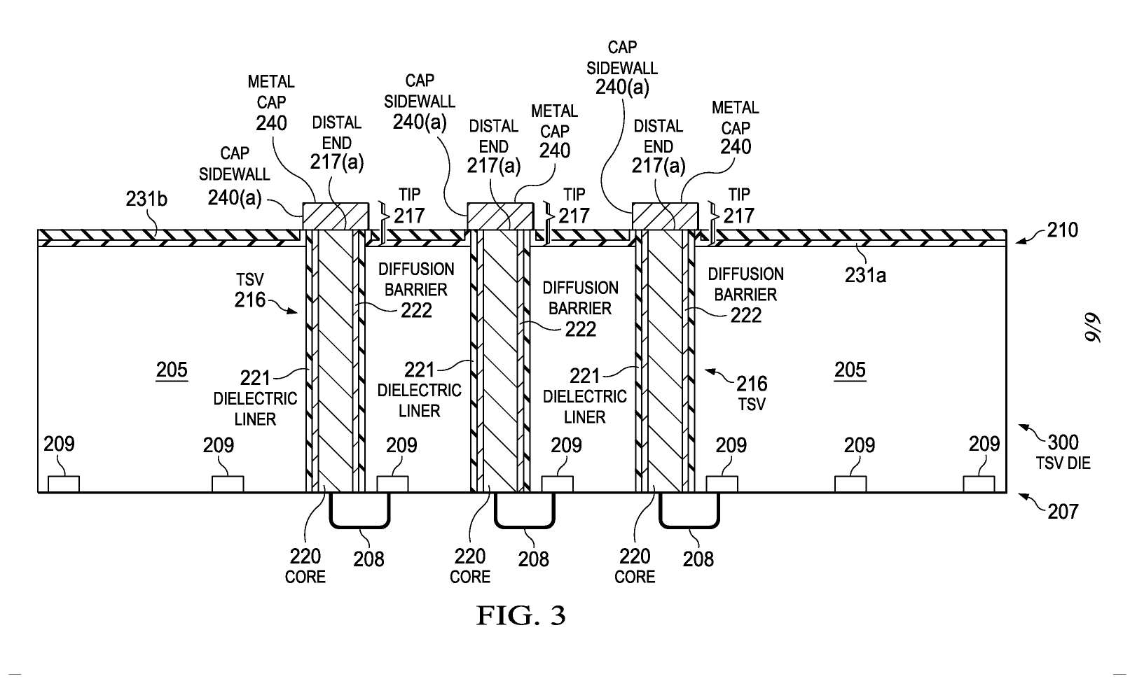

The top side semiconductor surface 207 includes active circuitry (see active circuitry 209 shown in FIG. 3). The embedded vias 276 are shown including a dielectric liner 221 (or dielectric sleeve) and diffusion barrier layer 222 with an inner metal core 220 within the diffusion barrier layer 222. The embedded vias 276 are generally coupled to the contact level or one of the BEOL metal layers (e.g., M1, M2, etc.) on the top side semiconductor surface 207. In one embodiment the embedded vias have a circular cross section including a diameter ≦12 μm, such as 3 μm to 10 μm in one particular embodiment.

The inner metal core 220 can comprise copper in one embodiment. Other electrically conductive materials can be used for the inner metal core 220. The dielectric liner 221 can comprise materials such as silicon oxide, silicon nitride, phosphorus-doped silicate glass (PSG), silicon oxynitride, or certain chemical vapor deposited (CVD) polymers (e.g., parylene). The dielectric liner 221 is typically 0.2 μm to 5 μm thick.

In the case of copper and certain other metals for the inner metal core 220, a diffusion barrier layer 222, such as a refractory metal or a refractory metal nitride, is generally added which can be deposited on the dielectric liner 221. For example, diffusion barrier layer 222 can include materials comprising Ta, W, Mo, Ti, TiW, TiN, TaN, WN, TiSiN or TaSiN, which can be deposited by physical vapor deposition (PVD) or CVD. The diffusion barrier layer 222 is typically 100 Å to 500 Å thick.

FIG. 2B shows a simplified cross sectional depiction of the wafer 230 shown in FIG. 2A after substrate (e.g., silicon) etch, which can include wet and/or dry etching, to expose the TSVs including forming TSV tips 217, now shown as wafer 230a and die 241a, 242a. TSV tips 217 extend from the top side semiconductor surface 207 to the bottom side surface 210 and protrude from the bottom side surface 210 of the substrate 205. In one embodiment a median length of the protruding TSV tips 217 measured from the bottom side surface 210 of the substrate is from 2 μm to 10 μm. As noted above, the metal interconnect and interlevel dielectric (ILD) layers on the top side semiconductor surface 207 (not shown) can exert a net tensile stress on the top side semiconductor surface 207.

Step 102 comprises depositing a dielectric stack on the bottom side surface 210, including step 102a comprising depositing a first compressive dielectric layer on the bottom side surface, and step 102b comprising depositing a tensile dielectric layer on the first compressive dielectric layer. Step 102c comprises optionally depositing a second compressive dielectric layer on the tensile dielectric layer.

FIG. 2C shows a simplified cross sectional depiction of the wafer 230a shown in FIG. 2B after depositing of a dielectric stack on the bottom side surface 210 of the substrate (step 102) now shown as wafer 230b and die 241b, 242b. The dielectric stack as shown includes a first compressive dielectric layer 231a on the bottom side surface 210, a tensile dielectric layer 231b on the first compressive dielectric layer 231a, and a second compressive dielectric layer 231c on the tensile dielectric layer 231b.

The first compressive dielectric layer 231a is generally 0.05 μm to 0.9 μm thick, and provides a compressive stress of about 50 to 175 MPa. The tensile dielectric layer 231b is generally 0.4 to 2.6 μm thick and provides a tensile stress of about 50 to 400 MPa. The first compressive dielectric layer 231a and the tensile dielectric layer 231b can both comprise silicon nitride (although non-stoichiometric, referred to herein as SiN). The second compressive dielectric layer 231c is generally 0.4 μm to 1.2 μm thick, provides compressive stress of about 30 to 250 MPa, and can comprise silicon oxide, such as TEOS derived silicon oxide in one particular embodiment.

The first compressive dielectric layer 231a provides electrical isolation of the substrate (e.g., Si) from the TSV tips 217 and can serve as a crack-arrest layer. The tensile dielectric layer 231b can provide sufficient tensile stress to compensate for stress on the top side surface of the substrate 205. The second compressive dielectric layer 231c serves as a sacrificial compressive dielectric film, which suppresses scratch-induced damage during CMP (which is a crack nucleating process), and protects underlying tensile dielectric layer 231b from potentially crack-causing CMP damage.

As known in the art, low pressure chemical deposition (LPCVD) parameters including temperature, total pressure, gas ratio and radio frequency (RF) power (for plasma-enhanced deposition processes) can be used to set the stress in a dielectric layer to be either compressive or tensile, and the magnitude thereof, such as for a SiN layer (See a paper by P. Temple-Boyer et al. “Residual stress in low pressure chemical vapor deposition SiNx films deposited from silane and ammonia” J. Vac. Sci. Technol. A 16, pages 2003-2007 (1998)). For example, the measured film stresses for plasma enhanced SiN can be designed to be anywhere in the range from about 300 MPa tensile to about 400 MPa compressive.

The tensile dielectric layer 231b on the first compressive dielectric layer 231a is the portion of the dielectric stack that provides front-side bow compensation after debond. The total thickness of the tensile dielectric layer 231b plus the first compressive dielectric layer 231a as noted above is generally 0.5 μm to 3.5 μm, typically being 0.8 μm to 1.6 μm.

In one particular embodiment, the first compressive dielectric layer 231a is a 0.15 μm to 0.25 μm SiN layer for crack suppression and TSV isolation from the substrate 205, the tensile dielectric layer 231b is a 0.8 μm to 1.2 μm SiN layer for achieving bow compensation, and the second compressive dielectric layer 231c is a sacrificial TEOS-derived silicon oxide layer to minimize the opportunity for CMP-induced cracking of the underlying tensile SiN layer that can otherwise occur when polish-revealing the distal end of the TSV tips 217. SiN has higher crack threshold for given tensile stress than silicon oxide, such as TEOS-derived silicon oxide.

Step 103 comprises CMP to re-expose (reveal) the distal end of the TSV tips 217. When the dielectric stack includes the second compressive dielectric layer 231c as shown in FIG. 2C, the CMP process can completely remove the second compressive dielectric layer 231c rendering it a sacrificial layer. The second compressive dielectric layer 231c can provide a helpful CMP endpoint signal since the second compressive dielectric layer 231c is generally a different material that provides a different CMP polish rate as compared to the tensile dielectric layer 231b.

FIG. 2D shows a cross sectional depiction showing the wafer 230b shown in FIG. 2C after complete removal of the second compressive dielectric layer 231c and re-exposing the distal end 217a of the TSV tips 217 (step 103), now shown as wafer 230c and die 241c, 242c. A small amount of the tensile dielectric layer 231b (e.g., 0.05 μm to 0.3 μm SiN) may be removed when the second compressive dielectric layer 231c (e.g., TEOS-derived silica) is removed by CMP. Following CMP, a process loop can be added to provide metal caps on the TSV tips.

FIG. 3 is a simplified cross sectional depiction of an example TSV die 300 having TSVs 216 including protruding TSV tips 217 extending out from bottom side surface 210 of the substrate 205 and a dielectric stack including a tensile dielectric layer 231b and a first compressive dielectric layer231a in the field regions between the TSV tips 217, according to an example embodiment. The TSV tips 217 are shown having metal caps 240 thereon. Although the metal cap 240 is shown as an electroless metal cap, the metal cap 240 may also be electroplated.

The dielectric stack 231b, 231a can be seen to be substantially flush with respect to the top of the inner metal core 220 at the TSV distal tip end 217(a). As used herein, “substantially flush” refers to a thickness of the dielectric stack 231b, 231a adjacent to the TSV 216 approximately equal to a length from the bottom side surface 210 to the distal tip end 217(a). The protruding TSV tips 217 are shown having an optional metal cap 240 on their distal tip ends 217(a). The sidewall of the metal cap 240 is shown as 240(a).

TSV die 300 comprises a substrate 205 including a top side semiconductor surface 207 including active circuitry 209 and a bottom side surface 210. The active circuitry 209 on TSV die 300 is configured to provide an IC circuit function, such as a logic function, for example. The connectors 208 shown depict the coupling between the TSVs 216 on the top side semiconductor surface 207 to the active circuitry 209. The connection provided by connectors 208 to the active circuitry 209 is optional, since the connection may simply pass through the substrate 205 without connecting to active circuitry 209, such as for a power supply connection.

The TSVs 216 comprise an outer dielectric sleeve (or dielectric liner) 221 and an inner metal core 220 comprising an electrically conductive filler material, and a diffusion barrier layer 222 between the dielectric sleeve 221 and the inner metal core 220. The TSVs 216 extends from the top side semiconductor surface 207 to protruding TSV tips 217 emerging from the bottom side surface 210 of substrate 205.

For example, in one particular embodiment the tip ends 217(a) of the TSV tips 217 extend out about 5 μm from the bottom side surface 210 of TSV die 300, the metal caps 240 add about 5 μm in height to the TSV tips 217, and the dielectric stack (231b, 231a) total thickness is in the range from 0.5 μm to 3.5 μm. The active circuitry 209 formed on the top side semiconductor surface 207 of the substrate 205 comprises circuit elements that may generally include transistors, diodes, capacitors, and resistors, as well as signal lines and other electrical conductors that interconnect the various circuit elements to provide an IC circuit function. As used herein “provide an IC circuit function” refers to circuit functions from ICs, that for example may include an application specific integrated circuit (ASIC), a digital signal processor, a radio frequency chip, a memory, a microcontroller and a system-on-a-chip or a combination thereof.

Advantages of disclosed TSV die having a plurality of TSVs including a bow compensating dielectric stack on the bottom side of the die, include avoiding the capital expense of purchasing an alternate bond/debond tool, and avoiding TSV tip deformation during die stacking/thermal-compression bonding with non-conductive paste (TCNCP) bonding which is common in polymeric electrical isolation integration schemes. Other advantages include providing crack suppression for an otherwise crack-susceptible tensile film such as SiN, and eliminating constraints to the IC fabrication facility to meet an imposed specification on outgoing wafer bow (which can force a major baseline process change).

Experiments were performed to evaluate crack arresting and wafer bow reduction performance of disclosed TSV wafers having a plurality of TSV die including a bow compensating dielectric stack on the bottom side of the TSV wafer. The dielectric stack included a 0.21 μm compressive SiN layer as the first compressive dielectric layer 231a and a tensile dielectric layer 231b shown as the 2^{nd} SiN layer which varied in thickness in the experiments performed from 1.0 μm to 1.8 μm. The TSV wafers were 300 mm bulk silicon wafers having a net tensile CMOS layer stack on the top side surface, including TSVs 216 having copper filler and TSV tips 217, that were measured after TSV tip reveal following debond. The bow height for the disclosed TSV wafers having the bow compensating dielectric stack were measured to be 5 mm to 9 mm, and no debonding problems were observed.

Process split data indicated at least 50% improvement in TSV wafer yield at debond as compared to the debond yield of TSV wafers without disclosed stress compensating dielectric stacks on the bottom side of the wafer. The bow height for disclosed TSV wafers of 5 mm to 9 mm was reduced about 80 to 90% from about 45 to 80 mm for the control TSV wafers. Reliability was also found to be improved by crack suppression properties of disclosed dielectric stacks.

Disclosed embodiments can be integrated into a variety of assembly flows to form a variety of different semiconductor integrated circuit (IC) devices and related products. The assembly can comprise single semiconductor die or multiple semiconductor die, such as PoP configurations comprising a plurality of stacked semiconductor die. A variety of package substrates may be used. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the semiconductor die can be formed from a variety of processes including bipolar, CMOS, BiCMOS and MEMS.

Those skilled in the art to which this disclosure relates will appreciate that many other embodiments and variations of embodiments are possible within the scope of the claimed invention, and further additions, deletions, substitutions and modifications may be made to the described embodiments without departing from the scope of this disclosure.

1. A through-substrate via (TSV) die, comprising:
a substrate having a top side semiconductor surface having active circuitry therein including a plurality of transistors functionally connected and a bottom side surface, wherein layers on said top side semiconductor surface exert a net tensile stress on said top side semiconductor surface;
a plurality of TSVs which extend from said top side semiconductor surface to TSV tips which protrude from said bottom side surface and comprise an inner metal core comprising an electrically conductive filler material surrounded by a dielectric liner that forms an outer edge for said plurality of TSVs, and
a dielectric stack on said bottom side surface lateral to said TSV tips including:
a compressive dielectric layer on said bottom side surface, and
a tensile dielectric layer on said compressive dielectric layer.

2. The TSV die of claim 1, wherein said substrate comprises silicon and said electrically conductive filler material comprises copper.

3. The TSV die of claim 1 wherein a thickness of said substrate between said top side semiconductor surface and said bottom side surface is 25 μm to 100 μm.

4. The TSV die of claim 1, wherein said compressive dielectric layer provides a compressive stress of 50 to 175 MPa and said tensile dielectric layer provides a tensile stress of 50 to 400 MPa.

5. The TSV die of claim 4, wherein said compressive dielectric layer comprises silicon nitride and said tensile dielectric layer comprises silicon nitride.

6. The TSV die of claim 1, wherein said TSV tips include metal caps thereon including a metal different from said electrically conductive filler material.

7. The TSV die of claim 1, wherein said compressive dielectric layer is 0.05 μm to 0.9 μm thick, and said tensile dielectric layer is from 0.4 μm to 2.6 μm thick.

8. A method of fabricating through-substrate via (TSV) die, comprising:
thinning from an initial bottom side of a substrate having a top side semiconductor surface having active circuitry therein including a plurality of transistors functionally connected attached to a carrier to reach a bottom side surface to expose a plurality of embedded filled vias to form a plurality of TSVs which extend from said top side semiconductor surface to TSV tips and protrude from said bottom side surface, wherein layers on said top side semiconductor surface exert a net tensile stress on said top side semiconductor surface;
depositing a dielectric stack on said bottom side surface lateral to said TSV tips including:
depositing a first compressive dielectric layer on said bottom side surface;
depositing a tensile dielectric layer on said first compressive dielectric layer, and
chemical mechanical polishing (CMP) to reveal distal tip ends of said TSV tips.

9. The method of claim 8, wherein said substrate is a silicon comprising wafer including a plurality of said TSV die.

10. The method of claim 8, wherein said depositing a dielectric stack further comprises depositing a second compressive dielectric layer on said tensile dielectric layer, wherein said CMP completely removes said second compressive dielectric layer.

11. The method of claim 10, wherein said depositing said second compressive dielectric layer comprises depositing silicon oxide using a process comprising flowing tetraethyl orthosilicate (TEOS).

12. The method of claim 8, wherein said plurality of TSVs include an electrically conductive filler material comprising copper.

13. The method of claim 8, wherein a thickness of said substrate between said top side semiconductor surface and said bottom side surface is 25 μm to 100 μm.

14. The method of claim 8, wherein said first compressive dielectric layer is 0.05 μm to 0.9 μm thick and provides a compressive stress of 50 to 175 MPa, and said tensile dielectric layer is 0.4 μm to 2.6 μm thick and provides a tensile stress of 50 to 400 MPa.

15. The method of claim 8, wherein said plurality of TSVs include electrically conductive filler material comprising copper, further comprising plating metal caps on said TSV tips including a metal different from said electrically conductive filler material.

16. The method of claim 8, wherein said first compressive dielectric layer comprises silicon nitride and said tensile dielectric layer comprises silicon nitride.
